(19) United States
(12) Patent Application Publication
(10) Pub. No.: US 2025/0216484 A1
(43) Pub. Date: Jul. 3, 2025

(54) MAGNETIC RESONANCE IMAGING SYSTEMS AND COIL INTERFACE DEVICES THEREOF

(71) Applicant: WUHAN UNITED IMAGING LIFE SCIENCE INSTRUMENT CO., LTD., Wuhan (CN)

(72) Inventors: Chuo XIE, Wuhan (CN); Dashen CHU, Shanghai (CN); Renkuan ZHAI, Wuhan (CN)

(73) Assignee: WUHAN UNITED IMAGING LIFE SCIENCE INSTRUMENT CO., LTD., Wuhan (CN)

(21) Appl. No.: 18/964,370

(22) Filed: Nov. 30, 2024

(30) Foreign Application Priority Data
Dec. 27, 2023 (CN) 202323625879.2
Dec. 27, 2023 (CN) 202323635096.2

(51) Int. Cl. G01R 33/34

(52) U.S. Cl. CPC G01R 33/34007

(57) ABSTRACT

A magnetic resonance imaging (MRI) system is provided. The MRI system includes a receiver channel configured to receive radio frequency signals, and a coil interface device configured to connect the MRI system with a radio frequency (RF) coil. The coil interface device includes a preamplifier, a quick disconnect connector, and a receiver channel interface One end of the quick disconnect connector is connected to the preamplifier and another end is configured to be connected to the RF coil. The quick disconnect connector is configured to be detachably connected to the RF coil. The receiver channel interface is configured to be connected to the receiver channel.

### CROSS-REFERENCE TO RELATED APPLICATIONS

This application claims priority to Chinese Patent Application No. 202323635096.2, filed on Dec. 27, 2023, and Chinese Patent Application No. 202323625879.2, filed on Dec. 27, 2023, the entire contents of each of which are hereby incorporated by reference.

### TECHNICAL FIELD

The present disclosure relates to the field of medical imaging, and in particular, to magnetic resonance imaging systems and coil interface devices for the magnetic resonance imaging systems.

### BACKGROUND

Radio frequency (RF) coils are crucial components of an MRI system, primarily responsible for emitting to and/or acquiring the magnetic resonance signals. In the MRI system, the RF coils come in various sizes tailored to different anatomical regions, with their design often based on the shape and size of the object. This customization ensures the effective emission and acquisition of the magnetic resonance signals for diverse objects. Traditionally, the RF coils are manufactured as complete units integrated with a fixed interface. Consequently, when different-sized RF coils are needed, the entire interface—comprising the RF coils—must be replaced. This integration poses a challenge for customization, as the RF coils and the interface are inseparable. Although researchers can design the RF coils to suit specific needs, there is currently no detachable interface device available, making it difficult to connect custom RF coils to the MRI system. Therefore, it is desirable to develop a solution for connecting custom RF coils to the MRI system.

### SUMMARY

One or more embodiments of the present disclosure provide a magnetic resonance imaging (MRI) system. The MRI system may include a receiver channel configured to receive radio frequency signals, and a coil interface device configured to connect the MRI system with a radio frequency (RF) coil. The coil interface device may include a preamplifier, a quick disconnect connector, and a receiver channel interface. One end of the quick disconnect connector may be connected to the preamplifier and another end may be configured to the RF coil. The quick disconnect connector may be configured to be detachably connected to the RF coil. The receiver channel interface may be configured to be connected to the receiver channel.

In some embodiments, the MRI system may further include a transmitter channel configured to transmit radio frequency signals. The coil interface device may further include a switching circuit. A first end of the switching circuit may be connected to the quick disconnect connector. A second end of the switching circuit may be configured to be connected to the transmitter channel. A third end of the switching circuit may be configured to be connected to the receiver channel via the preamplifier.

In some embodiments, the coil interface device may further include a transmitter channel interface. The transmitter channel interface may be configured to be connected between the switching circuit and the transmitter channel.

In some embodiments, the transmitter channel interface may be configured to be detachably connected to the transmitter channel. The receiver channel interface may be configured to be detachably connected to the receiver channel.

In some embodiments, the transmitter channel interface may be detachably connected to the transmitter channel through an RF pin and an RF socket; or the receiver channel interface may be detachably connected to the receiver channel through an RF pin and an RF socket.

In some embodiments, the coil interface device may further include a printed circuit board. The quick disconnect connector, the preamplifier, the switching circuit, the transmitter channel interface, and the receiver channel interface may be integrated on the printed circuit board.

In some embodiments, the coil interface device may further include a coil tuning device. The coil tuning device may be configured to be connected between the RF coil and the preamplifier.

In some embodiments, the coil interface device may be configured to be connected to a coil tuning device via the quick disconnect connector and a cable. The cable may be connected to the coil tuning device and the quick disconnect connector, respectively.

In some embodiments, the coil tuning device may be configured to be detachably connected to the RF coil via a tin soldering connection.

In some embodiments, the coil interface device may further include a second printed circuit board. The coil tuning device, the preamplifier, and the receiver channel interface may be integrated on the second printed circuit board.

In some embodiments, the coil tuning device may include a third printed circuit board, and the coil tuning circuit may be provided on the third printed circuit board. The coil interface device may further include a fourth printed circuit board. The preamplifier, the quick disconnect connector, and the receiver channel interface may be integrated on the fourth printed circuit board.

In some embodiments, the quick disconnect connector may be detachably connected to the RF coil via a separation quick locking assembly (SQLA) quick plug and socket.

In some embodiments, the coil interface device further may further include a plurality of quick disconnect connectors. The plurality of quick disconnect connectors may be configured to be detachably connected to a plurality of channels of the RF coil.

In some embodiments, the quick disconnect connector may include a first quick disconnect connector and a second quick disconnect connector. The first quick disconnect connector may be configured to be detachably connected to a channel of a first RF coil, and the second quick disconnect connector may be configured to be detachably connected to a channel of a second RF coil. A first spatial range of the first RF coil may be different from a second spatial range of the second RF coil, or a first polarized direction of the first RF coil may be different from a second polarized direction of the second RF coil. The first quick disconnect connector may be the same as the second quick disconnect connector.

In some embodiments, the coil interface device may further include a first switch and a second switch. The first switch may be configured to control connection and disconnection of the first RF coil, and the second switch may be configured to control connection and disconnection of the second RF coil.

In some embodiments, the coil interface device may further include a coil type determination module configured to determine a type of the RF coil. The coil type determination module may cause the RF coil to be connected to a circuit corresponding to the type of the RF coil.

In some embodiments, the RF coil may be an RF receiver coil or an integrated RF transceiver coil.

One or more embodiments of the present disclosure provide a coil interface device. The coil interface device may include a preamplifier and a quick disconnect connector. One end of the quick disconnect connector may be connected to the preamplifier and another end of the quick disconnect connector may be configured to be connected to an RF coil, and the quick disconnect connector may be configured to be detachably connected to the RF coil.

In some embodiments, the coil interface device may further include a coil tuning device. The coil tuning device may be configured to be connected between the quick disconnect connector RF coil and the preamplifier.

In some embodiments, the coil interface device may be configured to be connected to the coil tuning device via the quick disconnect connector and a cable. The cable may be connected to the coil tuning device and the quick disconnect connector, respectively.

One or more embodiments of the present disclosure provide a magnetic resonance imaging (MRI) system. The MRI system may include a coil interface device, a scanning bed, and a scanning cavity. The coil interface device may include a quick disconnect connector and a preamplifier. One end of the quick disconnect connector may be connected to the preamplifier and another end of the quick disconnect connector is detachably connected to an integrated transceiver coil. The scanning bed and the coil interface device enter the scanning cavity when performing magnetic resonance imaging.

One or more embodiments of the present disclosure provide a magnetic resonance imaging (MRI) system. The MRI system may include a coil interface device, a scanning bed, and a scanning cavity. One end of the coil interface device may be welded to an RF coil and another end of the coil interface device may include a receiver channel interface. The receiver channel interface is matched to a system interface of the MRI system. The RF coil is connected to the MRI system through a connection between the receiver channel interface and the system interface. The scanning bed and the coil interface device enter the scanning cavity when performing magnetic resonance imaging.

The above-described MRI system may include a coil interface device, a scanning bed, and a scanning cavity. The coil interface device may include a quick disconnect connector and a preamplifier. One end of the quick disconnect connector is connected to the preamplifier and another end of the quick disconnect connector is detachably connected to an integrated transceiver coil. The scanning bed and the coil interface device enter the scanning cavity when the magnetic resonance imaging is performed. In the MRI system, by setting the coil interface device, and setting the quick disconnect connector and the preamplifier in the coil interface device, the coil interface may be connected with the coil interface in the integrated transceiver coil through the quick disconnect connector. Thus, the integrated transceiver coil may be easily connected to the MRI system. In addition, if the research user makes his own coil, the coil may be connected to the MRI system through the coil interface device.

The above-described MRI system may include a coil interface device, a scanning bed, and a scanning cavity. One end of the coil interface device may be welded to an RF coil and another end of the coil interface device may include a receiver channel interface. The receiver channel interface is matched to a system interface in the MRI system. The RF coil is connected to the MRI system through a connection between the receiver channel interface and the system interface. The scanning bed and the coil interface device enter the scanning cavity when the magnetic resonance imaging is performed. In the MRI system, by providing the coil interface device and providing the receiver channel interface in the coil interface device that matches the system interface in the MRI system, the receiver channel interface may be easily connected to the system interface. Therefore, when the RF coil is soldered to the coil interface device, the RF coil may be connected to the MRI system by connecting the receiver channel interface of the coil interface device to the system interface in the MRI system, realizing the compatibility of the RF coil with the MRI system.

### BRIEF DESCRIPTION OF THE DRAWINGS

The present disclosure is further illustrated in terms of exemplary embodiments. These exemplary embodiments are described in detail with reference to the drawings. These embodiments are non-limiting exemplary embodiments, in which like reference numerals represent similar structures, and wherein:

FIG. 1 is a schematic diagram illustrating an application scenario of a magnetic resonance imaging (MRI) system according to some embodiments of the present disclosure;

FIG. 2A is a schematic diagram illustrating an exemplary structure of a coil interface device according to some embodiments of the present disclosure;

FIG. 2B is a schematic diagram illustrating an exemplary RF coil according to some embodiments of the present disclosure;

FIG. 3A is a schematic diagram illustrating a plurality of exemplary quick disconnect connectors according to some embodiments of the present disclosure;

FIG. 3B is a schematic diagram illustrating exemplary switches according to some embodiments of the present disclosure;

FIG. 4 is a schematic diagram illustrating an exemplary switching circuit according to some embodiments of the present disclosure;

FIG. 5 is a schematic diagram illustrating an exemplary transmitter channel interface and an exemplary receiver channel interface according to some embodiments of the present disclosure;

FIG. 6 is a schematic diagram illustrating an exemplary radio frequency switch according to some embodiments of the present disclosure;

FIG. 7 is a schematic diagram illustrating an exemplary first printed circuit board according to some embodiments of the present disclosure;

FIG. 8 is a schematic diagram illustrating another exemplary receiver channel interface according to some embodiments of the present disclosure;

FIG. 9A is a schematic diagram illustrating an exemplary coil tuning device according to some embodiments of the present disclosure;

FIG. 9B is a schematic diagram illustrating an exemplary coil tuning device according to some embodiments of the present disclosure;

FIG. 10 is a schematic diagram illustrating an exemplary coil tuning circuit according to some embodiments of the present disclosure;

FIG. 11 is a schematic diagram illustrating an exemplary coil interface device according to other embodiments of the present disclosure;

FIG. 12 is a schematic diagram illustrating an exemplary printed circuit board according to some embodiments of the present disclosure;

FIG. 13 is a schematic diagram illustrating an exemplary third printed circuit board according to some embodiments of the present disclosure;

FIG. 14 is a schematic diagram illustrating an exemplary cable according to some embodiments of the present disclosure;

FIG. 15 is a schematic diagram illustrating an exemplary magnetic resonance imaging (MRI) system according to some embodiments of the present disclosure.

FIG. 16 is a schematic diagram illustrating an exemplary structure of a quick disconnect connector according to some embodiments of the present disclosure;

FIG. 17 is a schematic diagram illustrating an exemplary circuit structure of a switching circuit according to some embodiments of the present disclosure;

FIG. 18A is a schematic diagram illustrating an exemplary structure of a system interface according to some embodiments of the present disclosure;

FIG. 18B is a schematic diagram illustrating an exemplary structure of a system interface according to some embodiments of the present disclosure; and

FIG. 19 is a schematic diagram illustrating an exemplary coil tuning circuit according to some embodiments of the present disclosure.

### DETAILED DESCRIPTION

To more clearly illustrate the technical solutions related to the embodiments of the present disclosure, a brief introduction of the drawings referred to the description of the embodiments is provided below. Obviously, the drawings described below are only some examples or embodiments of the present disclosure. Those having ordinary skills in the art, without further creative efforts, may apply the present disclosure to other similar scenarios according to these drawings. Unless obviously obtained from the context or the context illustrates otherwise, the same numeral in the drawings refers to the same structure or operation.

It should be understood that “system”, “device”, “unit” and/or “module” as used herein is a manner used to distinguish different components, elements, parts, sections, or assemblies at different levels. However, if other words serve the same purpose, the words may be replaced by other expressions. As shown in the present disclosure and claims, the words “one”, “a”, “a kind” and/or “the” are not especially singular but may include the plural unless the context expressly suggests otherwise. In general, the terms “comprise”, “comprises”, “comprising”, “include”, “includes”, and/or “including”, merely prompt to include operations and elements that have been clearly identified, and these operations and elements do not constitute an exclusive listing. The methods or devices may also include other operations or elements.

The flowcharts used in the present disclosure illustrate operations that systems implement according to some embodiments of the present disclosure. It should be understood that the previous or subsequent operations may not be accurately implemented in order. Instead, each step may be processed in reverse order or simultaneously. Meanwhile, other operations may also be added to these processes, or a certain step or several steps may be removed from these processes.

Magnetic resonance imaging (MRI) is a diagnostic technique by reconstructing images using signals generated by the resonance of atomic nuclei in a magnetic field. The basic principle lies in the atomic nuclei containing a single number of protons (for example, hydrogen nuclei widely found in the animal body or the human body) having a spin movement in its protons. These positively charged protons generate a magnetic moment, behaving like a small magnet. There is no certain regularity in the arrangement of the spin axis of the small magnet. However, in a uniformly strong magnetic field, the spin axis of the small magnet may be rearranged in the direction of the magnetic field lines. In this state, with a specific frequency of radio frequency (RF) pulses for excitation, the hydrogen nucleus, as a small magnet, absorbs a certain amount of energy and resonance, that is, the magnetic resonance phenomenon occurs. To stop transmitting RF pulses, the excited hydrogen nucleus will gradually release the absorbed energy, and its phase and energy level are restored to the pre-excitation state.

The MRI utilizes characteristics of the spin motion of atomic nuclei in an applied magnetic field to produce a signal after being applied a magnetic field. The signal is detected by a detector and input into a computer and then is processed for conversion to display an image on a screen. This process is called a nuclear magnetic resonance imaging process.

An MRI system mainly consists of a magnet, a gradient coil, an RF coil, and a spectrometer system. The gradient coil is configured to spatially encode the localization and generate a gradient magnetic field. The RF coil typically includes a transmitter coil, a receiver coil, or an integrated transceiver coil according to coil functions. The transmitter coil is similar to a shortwave transmitter or a transmitter antenna that transmits pulses to an object for excitation with an appropriate RF wave. The receiver coil (RF coil) is configured only to receive MRI signals. The RF coil includes a surface coil, a body coil, etc. The integrated transceiver coil is a transmitter coil integrated with a receiver coil to both transmit and receive RF pulses. The integrated transceiver coil usually uses a transmitter coil to generate a transmitting field and uses a receiver coil to receive the MRI signals. The transmitting field may flip protons and the MRI signals recovered from the relaxation of the protons are received by the receiver coil.

The RF coils may be different for different examined sites (e.g., different body parts of a patient, different body parts of an animal phantom, etc.). For example, for the head, the body, the limbs, and the abdomen that are highly varied, required coverage areas of the RF coils (i.e., an acquisition area) and requirements for the shape of the RF coils are also different.

In the related art, a preamplifier of the RF coil is typically integrated into the MRI system, and the preamplifier is connected to the RF coil via a cable to access the RF coil into the MRI system. In addition, the RF coils of different sizes and shapes are usually developed based on information such as the shape and size of an object.

After developing a new RF coil, it is necessary to connect the developed RF coil to the MRI system. Therefore, the way of connecting the developed RF coil into the MRI system has become an urgent technical problem.

In view of the foregoing, some embodiments of the present disclosure provide a coil interface device for an MRI system. The coil interface device includes a preamplifier and a quick disconnect connector. One end of the quick disconnect connector is connected to the preamplifier, and another end is connected to an RF coil. The quick disconnect connector is be configured to be detachably connected to the RF coil. Convenient and rapid detachable connection between the RF coil and the MRI system is achieved by the quick disconnect connector.

The detachable connection enables the access of the RF coil to the MRI system with the following features. First, the replacement of the RF coil is convenient. Users may replace different RF coils or interface devices as required to meet the needs of specific scenarios or uses. Second, the detachable connection is easy to clean and maintain, thereby extending the service life of the interface device. Third, the detachable connection may be folded or separated for easy storage and carrying, thereby enhancing portability. Fourth, users can choose different sizes and shapes of RF coils for personalization. Fifth, costs are reduced. When the interface device or a part of the RF coil is damaged, only one of the parts needs to be replaced, rather than replacing the entire MRI device, thereby reducing maintenance costs.

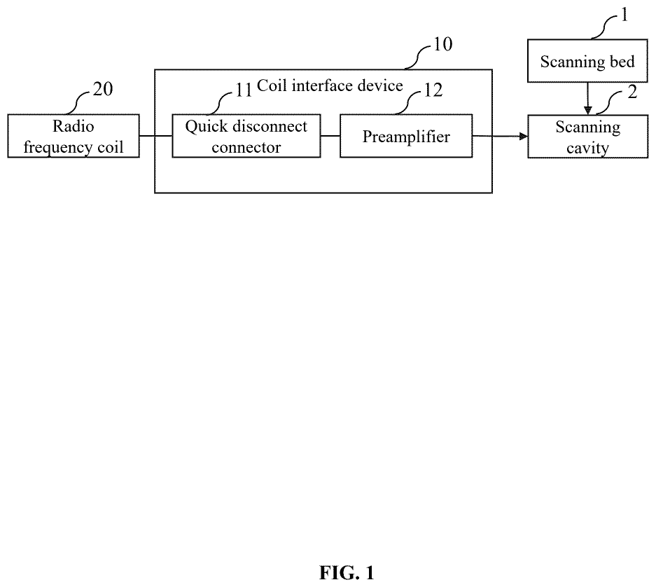

FIG. 1 is a schematic diagram illustrating an application scenario of a magnetic resonance imaging (MRI) system according to some embodiments of the present disclosure.

In some embodiments, as shown in FIG. 1, an MRI system includes a coil interface device 10, a scanning bed 1, and a scanning cavity 2.

The coil interface device 10 includes a quick disconnect connector 11 and a preamplifier 12. One end of the quick disconnect connector 11 is connected to the preamplifier 12, and the other end of the quick disconnect connector 11 is configured to be detachably connected to a radio frequency (RF) coil 20. In some embodiments, the MRI system also includes at least one transmitter channel and at least one receiver channel (not shown in FIG. 1, shown in FIG. 5). The at least one transmitter channel is configured to transmit radio frequency signals. The at least one receiver channel is configured to receive radio frequency signals. In some embodiments, the quick disconnect connector 11 is configured to connect the transmitter channel or the receiver channel of the MRI system with the RF coil. In some embodiments, the coil interface device 10 includes a plurality of quick disconnect connectors 11, and the plurality of quick disconnect connectors 11 are configured to connect a plurality of transmitter channels or a plurality of receiver channels of the MRI system with the RF coil. In some embodiments, the scanning bed 1 and the coil interface device 10 are accessible to the scanning cavity 2 when an MRI process is performed.

In some embodiments, the MRI system may be used for preclinical research, equipment research improvement, and animal magnetic resonance imaging. The scanning bed 1 may be configured to place an object to be scanned, which may include experimental animals (such as a mouse) or phantoms. During magnetic resonance imaging, the object to be scanned may be placed on the scanning bed 1 and enter into the scanning cavity 2 together with the coil interface device 10 to scan the object to be scanned. The MRI system may also include a magnet. A magnetic field strength of the magnet includes 5T, 7T, or 9.4T or more.

In some embodiments, the RF coil is an RF receiver coil. The RF coil is connected to one end of the coil interface device 10, and another end of the coil interface device 10 includes a receiver channel interface (not shown). The receiver channel interface matches a system interface (not shown) in the MRI system. For example, the receiver channel interface is configured to be detachably connected to a receiver channel of the MRI system.

In some embodiments, the system interface in the MRI system may be an RF interface. The RF interface transmits analog signals to minimize the loss of RF signals. The RF interface may include an RF connector such as a snap-fit connector, a small threaded connector for coaxial connections, and a push-lock RF coaxial connector, etc.

In some embodiments, a type of the receiver channel interface may be determined based on an interface type of the system interface of the MRI system. For example, if the system interface of the MRI system is a snap-fit connector, the receiver channel interface is an interface that matches the snap-fit connector.

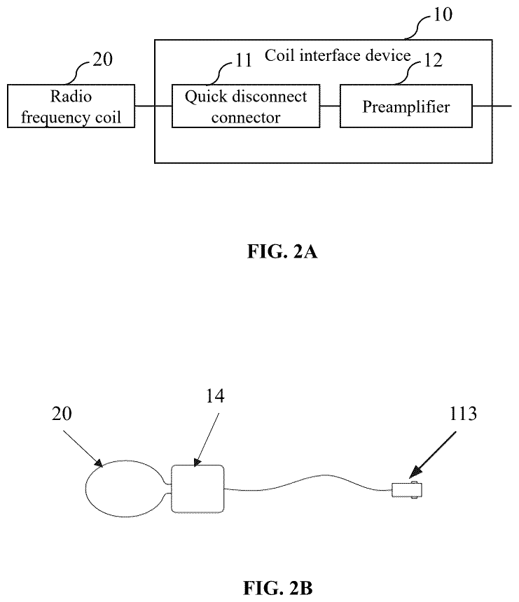

FIG. 2A is a schematic diagram illustrating an exemplary structure of a coil interface device according to some embodiments of the present disclosure. FIG. 2B is a schematic diagram illustrating an exemplary RF coil according to some embodiments of the present disclosure.

As shown in FIG. 2A, the coil interface device 10 may be used in a magnetic resonance imaging (MRI) system including a preamplifier 12 and a quick disconnect connector 11.

The preamplifier refers to a circuit or an electronic device that is placed between a source and an amplifier stage. The preamplifier is a first amplifier stage in an amplifier circuit for amplifying an input signal to a level sufficient to be processed by a subsequent amplifier or a subsequent processing circuit. The preamplifier 12 may include a current-sensitive preamplifier, a parasitic capacitance preamplifier, a charge-sensitive preamplifier, or the like.

Without a preamplifier, a final signal may be noisy or distorted. Therefore, the preamplifier may be placed close to the RF coil to minimize the effects of noise and interference. The preamplifier of the RF coil in related technology is integrated in a spectrometer. The preamplifier of the RF coil is located away from the RF coil and the preamplifier connects to the RF coil via a cable in the MRI system. Such a cable connection introduces a cable loss, and the longer the length of the cable, the more the signal is attenuated, which results in a reduction in the quality of MRI signals, and thus a reduction in the signal-to-noise ratio. The cable loss refers to a signal loss caused by the cable during a signal transmission process, which mainly occurs during a conversion of electrical energy to thermal energy during the signal transmission process. When a signal is transmitted from a transmitting end to a receiving end through a cable, the signal is gradually weakened due to the resistance, conductivity, and dielectric loss of the cable, resulting in a degradation of signal quality.

To further improve the signal-to-noise ratio of the RF coil, the preamplifier may be selected as a low noise preamplifier. Noise mixed in the signal, noise in the amplifiers, and interference induced during a connection process with the RF coil are amplified equally through the amplifier of each stage, thereby increasing the noise in the MRI signals. It is therefore important to minimize the noise of the amplifier to reduce the interference of the MRI signals. Based on this, in order to minimize noise and interference, the preamplifier is the low noise preamplifier.

The quick disconnect connector is a connector that makes electrical connections by quick plugging and quick unplugging. The quick disconnect connector facilitates quick operation and improves the efficiency and convenience of connecting components to each other. For example, fast plugging and unplugging speeds of the quick disconnect connector may reduce device failures due to poor connections or poor contact and improve device reliability.

In some embodiments, one end of the quick disconnect connector 11 is connected to the preamplifier 12, and another end of the quick disconnect connector 11 is be configured to be connected to the RF coil 20. The quick disconnect connector 11 is configured to be detachably connected to the RF coil 20.

Instead of connecting the RF coil 20 to the preamplifier 12 via a cable, the RF coil 20 is connected to the preamplifier 12 via the quick disconnect connector 11 in the embodiment of the present disclosure, which both avoids the problem of introducing loss due to the connection of the cable and reduces the effect of noise and interference.

In an embodiment of the present disclosure, the quick disconnect connector 11 is provided in the coil interface device 10, which may be connected to the RF coil 20 through the quick disconnect connector 11, so as to allow the RF coil 20 to be plugged and unplugged to the MRI system through the quick disconnect connector. For example, the RF coil 20 may be plugged and unplugged to the MRI system through another end of the preamplifier 20.

Embodiments of the present disclosure provide a coil interface device including a quick disconnect connector and a preamplifier. One end of the quick disconnect connector is connected to the preamplifier, and another end of the quick disconnect connector is configured to be detachably connected to an RF coil. When applying the coil interface device to the MRI system for magnetic resonance imaging, the scanning bed and the coil interface device enter into the scanning cavity. At this time, in the MRI system, by providing the coil interface device with the quick disconnect connector and the preamplifier in the coil interface device, a connection to a coil interface of the RF coil may be made through the quick disconnect connector, thereby allowing the RF coil to be quickly accessed into the MRI system. Additionally, if a research user customizes a coil, the customized coil may also be quickly accessed to the MRI system through the coil interface device, which effectively improves the efficiency and convenience of accessing the customize coil to the MRI system.

The RF coil refers to a device used in the MRI system to generate and receive RF signals. The RF coil excites nuclear spins in a sample by generating an alternating electromagnetic field, which in turn receives signals emitted by the sample for imaging and analysis.

In some embodiments, the RF coil may include a RF transmitter coil, a RF receiver coil, and an integrated RF transceiver coil. The RF transmitter coil, radiating electromagnetic waves of a certain frequency and power, causes hydrogen protons within a body to be excited and resonate. The RF receiver coil is configured to receive RF signals. The integrated RF transceiver coil is configured to both transmit and receive RF signals, and switch between transmitting and receiving through a circuit therein.

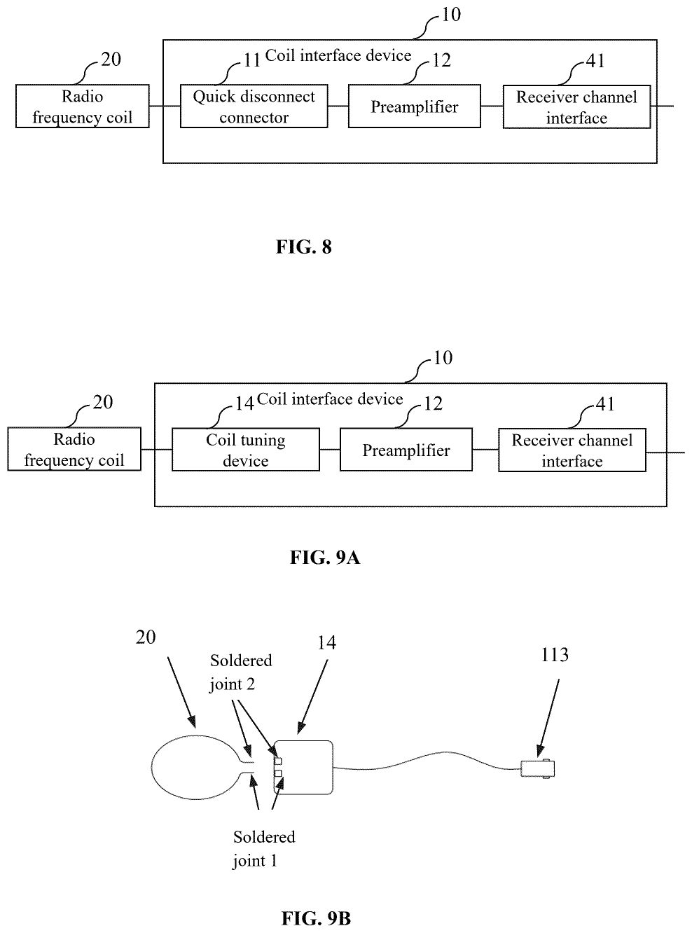

In some embodiments, as shown in FIG. 2B, the RF coil 20 (e.g., the integrated RF transceiver coil) further includes a coil tuning device 14 within. The coil interface device 10 is configured to be connected to the coil tuning device 14 of the integrated RF transceiver coil via the quick disconnect connector 113. The quick disconnect connector 113 can be any of the sub or parent interfaces of the quick disconnect connector 11. More description regarding the coil tuning device 14 can be found in FIG. 9A.

In some embodiments, the coil interface device 10 may include a plurality of quick disconnect connectors 11. The plurality of quick disconnect connectors 11 are configured to be detachably connected to a plurality of channels of the RF coil. Each channel of the RF coil corresponds to a sub-RF coil, and a plurality of sub-RF coil are integrated as a whole RF coil that is configured to transmit or receive RF signals. In some embodiments, the plurality of quick disconnect connectors 11 are configured to connect the plurality of transmitter channels or receiver channels of the MRI system with the plurality of channels of the RF coil.

In the embodiment of the present disclosure, by providing the plurality of quick disconnect connectors to connect the plurality of transmitter channels or receiver channels of the MRI system with the plurality of channels of the RF coil, the RF coil corresponding may be quickly plugged and quick unplugged into the MRI system.

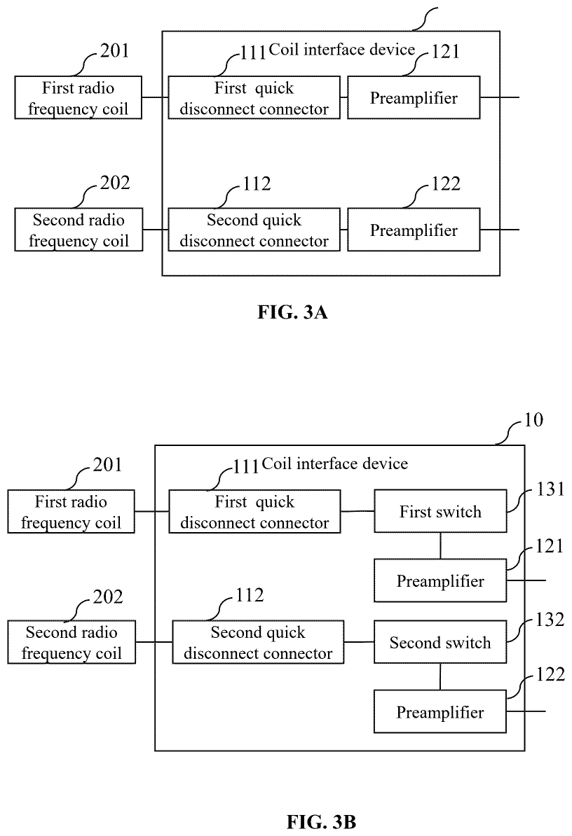

Taking the coil interface device 10 including two quick disconnect connectors 11 as shown in FIG. 3A as an example, FIG. 3A is a schematic diagram illustrating a plurality of exemplary quick disconnect connectors according to some embodiments of the present disclosure. Two quick disconnect connectors and two preamplifiers 12 are included in the coil interface device 10. The two quick disconnect connectors may be connected to two coil interfaces of the two RF coils, respectively, to make it possible to simultaneously connect the two RF coils to the MRI system.

In some embodiments, the quick disconnect connectors include a first quick disconnect connector 111 and a second quick disconnect connector 112.

The first quick disconnect connector 111 is configured to be detachably connected to a channel of a first RF coil 201 and the second quick disconnect connector 112 is configured to be detachably connected to a channel of a second RF coil 202. The other end of the first quick disconnect connector 111 is connected to the preamplifier 121, and the other end of the second quick disconnect connector 112 is connected to the preamplifier 122. In some embodiments, a first spatial range of the first RF coil is different from a second spatial range of the second RF coil, or a first polarized direction of the first RF coil is different from a second polarized direction of the second RF coil, however the first quick disconnect connector 111 is the same as the second quick disconnect connector 112. As used herein, a spatial range of a RF coil refers to a spatial range in which an energy that excites electromagnetic waves can reach (for a RF transmitter coil) or a spatial range in which RF signals can be detected (for a RF receiver coil). Different spatial ranges correspond to different shapes of the RF coils. A polarized direction of a RF coil includes a linear polarization, a circular polarization, an elliptical polarization, etc.

In some embodiments, the first quick disconnect connector 111 is the same as the second quick disconnect connector 112 means that interface standards, transmission speeds, transmission models, and geometrical parameters of the first quick disconnect connector 111 and the second quick disconnect connector 112 are the same. In some embodiments, depending on the specific application and equipment design (e.g., different RF coils are required when detecting different spatial ranges), there may be a plurality of transmitter and receiver coils, and in this embodiment, by setting the first quick disconnect connector 111 and the second quick disconnect connector 112 to be the same, it is possible to enable different RF coils (different shapes of RF coils) to be connected with the same quick disconnect connector, which not only meets the needs of different imaging requirements, but also improves the compatibility.

Taking the coil interface device 10 including two quick disconnect connectors 11 as an example, the coil interface device 10 may also include a first switch 131 and a second switch 132. A switch is a control structure for controlling a turn-on and a turn-off of a circuit.

The first switch 131 is configured to control a connection and a disconnection of the first RF coil into the MRI system, and the second switch 132 is configured to control a connection and a disconnection of the second RF coil into the MRI system. FIG. 3B is a schematic diagram illustrating exemplary switches according to some embodiments of the present disclosure. As shown in FIG. 3B, the first switch 131 may be configured to control the connection and disconnection between the first RF coil 201 and the preamplifier 121, and the second switch 132 may be configured to control the connection and disconnection between the second RF coil 202 and the preamplifier 122.

In some embodiments, the first switch 131 or the second switch 132 may be implemented by way of switching circuits. For example, both the first switch 131 and the second switch 132 may be implemented by way of switching circuits.

In some embodiments, the first switch 131 or the second switch 132 may also be implemented by way of a mechanical switch, which is not limited by this embodiment.

In this embodiment, by accessing a plurality of RF transmitter coils and RF receiver coils and using a plurality of switches each of which corresponds to a RF coil to control different RF coils to connect or disconnect with the MRI system, quickly switching between the different RF coils may be achieved.

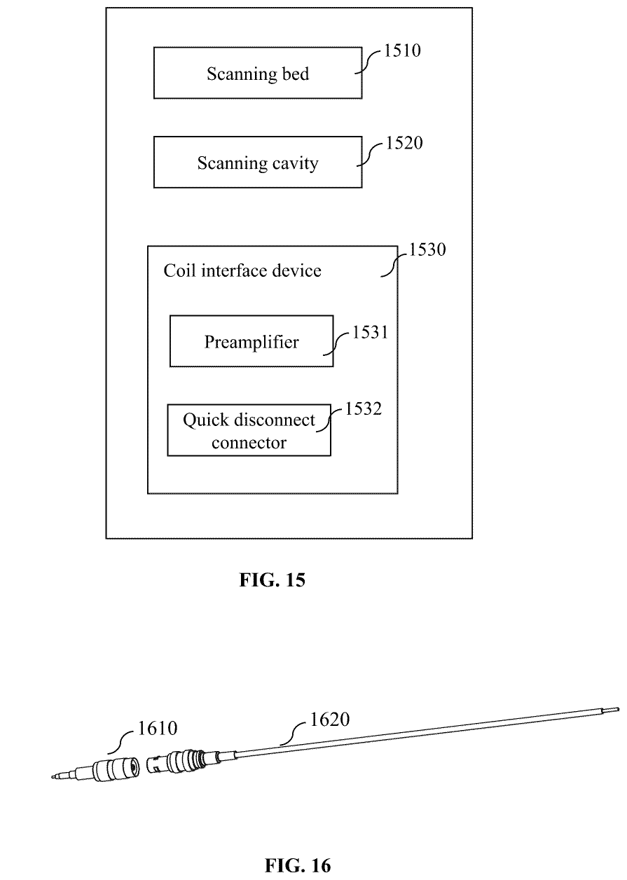

On the one hand, the intelligent control of the access and switching of the different RF coil is realized by the first switch 131 or the second switch 132, which may also be combined with a coil type determination module (descriptions of the coil type determination module may be found in FIG. 15A) to further determine a type of a RF coil to be accessed first, and then determine a connection state and a disconnection state of the first switch 131 or the second switch 132. On the other hand, the first switch 131 or the second switch 132 may also be combined with other systems, such as a remote control system, an automatic control system, and an alarming system in case of inappropriate coils, etc., to further improve the convenience of accessing RF coils in the MRI system.

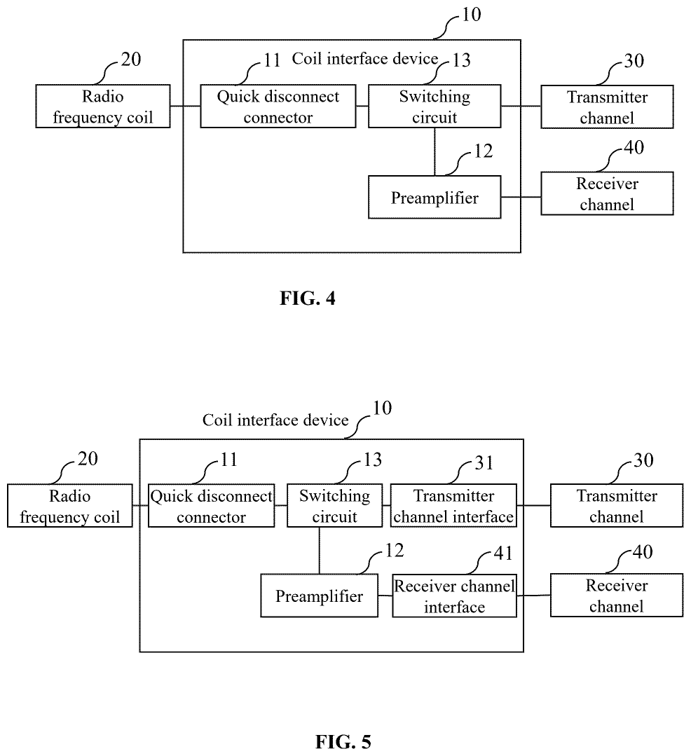

The first switch 131 or the second switch 132 may be implemented according to a switching circuit. More detailed descriptions regarding the switching circuits may be found in FIG. 4 and related descriptions hereinafter.

In this embodiment, the connection and disconnection of the RF coils is controlled by the first switch 131 and/or the second switch 132, which may be conveniently and quickly realized for the accessing control of the RF coils.

In some embodiments, the quick disconnect connector is configured to be detachably connected to the RF coil via a separation quick locking assembly (SQLA) quick plug and socket.

In this embodiment, the detachable connection of the quick disconnect connector to the RF coil is realized by the SQLA quick plug and socket, which may increase the speed of the disassembly and the connection, and the user operation is convenient. And it is possible to make the connection and disassembly of the quick disconnect connector fast, which may reduce the failure due to a poor connection or poor contact, and improve the reliability of the RF coils.

In some embodiments, the RF coil 20 may both transmit and receive RF pulses. In some embodiments, the RF coil 20 includes a surface coil and a body coil.

For example, the RF coil 20 may be an integrated transceiver coil. The integrated transceiver coil does not operate by receiving and transmitting at the same time, but rather, it switches rapidly between transmitting and receiving via electronic circuits to transmit the RF pulses and receive MRI signals. Based on this, the integrated transceiver coil, when plugged into the MRI system, requires certain equipment (e.g., a switching circuit) to realize the switching between transmitting RF pulses and receiving RF pulses.

FIG. 4 is a schematic diagram illustrating an exemplary switching circuit according to some embodiments of the present disclosure.

In some embodiments, as shown in FIG. 4, the coil interface device 10 further includes a switching circuit 13. A first end of the switching circuit 13 is connected to the quick disconnect connector 11, a second end of the switching circuit 13 is configured to be connected to the transmitter channel 30 of the MRI system, and a third end of the switching circuit is configured to be connected to a receiver channel 40 of the MRI system via the preamplifier 12.

The switching circuit refers to a circuit that controls a turn-on or turn-off state of a device with which the switching circuit is connected.

The transmitter channel 30 refers to a channel of the MRI system that controls transmission of RF pulses. The transmitter channel 30 may include a transmitter controller, a mixer, an attenuator, a power amplifier, or the like. The receiver channel 40 refers to a channel of the MRI system that controls the receipt of RF pulses. The receiver channel 40 may include a low-noise amplifier, an attenuator, a filter, a phase detector, a low-pass filter, and an analog-to-digital converter, or the like.

The switching circuit includes two or more electronic components connected separately. The switching circuit may include a conductive switch, an inductive switch, etc. The conductive switch controls a current flow of the switching circuit, and the inductive switch controls a voltage change of the switching circuit. When a component in the switching circuit functions in a “turn-on” state, current or voltage flows between the components. When a component in the switching circuit functions in a “turn-off” state, no current or voltage flows between the components.

In the embodiment of the present disclosure, by providing the switching circuit 13 in the coil interface device 10 and connecting the switching circuit 13 to the quick disconnect connector 11, the transmitter channel 30 of the MRI system, and the receiver channel 40 of the MRI system, respectively, the integrated transceiver coil may be switched to the transmitter channel via the switching circuit 13 when the integrated transceiver coil is required to transmit the RF pulses, and the integrated transceiver coil may be switched to the receiver channel via the switching circuit 13 when the integrated transceiver coil is required to receive the RF pulses.

In this way, fast switching of the integrated transceiver coil to transmit RF pulses and to receive RF pulses may be realized by the switching circuit. That is to say, when the integrated transceiver coil is required to transmit the RF pulses, the integrated transceiver coil is switched to the transmitter channel by the switching circuit and when the integrated transceiver coil is required to transmit the RF pulses, the transceiver coil is switched to the receiver channel by the switching circuit.

FIG. 5 is a schematic diagram illustrating an exemplary transmitter channel interface and an exemplary receiver channel interface according to some embodiments of the present disclosure.

In some embodiments, the coil interface device 10 further include a transmitter channel interface 31 and a receiver channel interface 41. The transmitter channel interface 31 is configured to be connected between the switching circuit 13 and the transmitter channel 30 of the MRI system. The receiver channel interface 41 is configured to be connected between the preamplifier 12 and the receiver channel 40 of the MRI system.

Corresponding channel interfaces are provided in both the transmitter channel and the receiver channel of the MRI system. Therefore, when accessing the RF coil into the MRI system via the coil interface device, it is also necessary for the coil interface device to provide corresponding transmitter channel interface and the receiver channel interface, to access the RF coil into the MRI system through the connection of the transmitter channel interface to the transmitter channel and the connection of the receiver channel interface to the receiver channel.

In some embodiments, the transmitter channel interface is configured to be detachably connected to the transmitter channel of the MRI system. The receiver channel interface is configured to be detachably connected to the receiver channel of the MRI system.

In the embodiment of the present disclosure, the transmitter channel interface 31 is configured to be detachably connected to the transmitter channel 30, and the receiver channel interface 41 is configured to be detachably connected to the receiver channel 40.

The transmitter channel interface 31 is connected between the switching circuit 13 and the transmitter channel 30, which may realize the connection between the integrated transceiver coil and the transmitter channel 30. The receiver channel interface 41 is connected between the preamplifier 12 and the receiver channel 40, which may realize the connection between the integrated transceiver coil and the receiver channel 40. When the integrated transceiver coil is required to transmit RF pulses, the transmitter channel 30 may send a command to transmit the RF pulses to the switching circuit 13 through the transmitter channel interface 31 to cause the switching circuit 13 to switch the integrated transceiver coil (e.g., the integrated transceiver coil) to the transmitter channel. When the integrated transceiver coil is required to receive the RF pulses, the receiver channel 40 may send a command to receive the RF pulses to the switching circuit 13 via the receiver channel interface 41 to cause the switching circuit 13 to switch the integrated transceiver coil (e.g., the integrated transceiver coil) to the receiver channel.

In some embodiments, the transmitter channel interface 31 is detachably connected to the transmitter channel 30 of the MRI system via an RF pin and an RF socket. The receiver channel interface 41 is detachably connected to the receiver channel 40 of the MRI system via an RF pin and an RF socket.

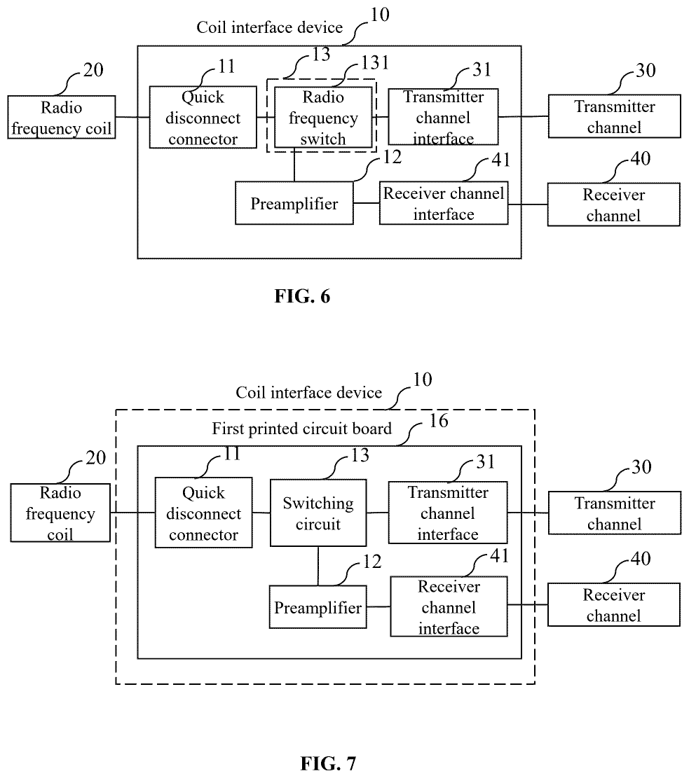

FIG. 6 is a schematic diagram illustrating an exemplary radio frequency switch according to some embodiments of the present disclosure.

The selection of the switching circuit also affects the signal-to-noise ratio of the coil. Thus, a RF switch may be selected as the switching circuit to further improve the signal-to-noise ratio of the coil. Based on this, in some embodiments, the switching circuit 13 include an RF switch 131 as shown in FIG. 6.

The RF switch is a device configured to switch and select wireless high-frequency signals. The RF switch controls the transmission or disconnection of signals based on electrical characteristics. The interior of the RF switch typically includes a plurality of units, each unit including a switching element and a matching network. The signals are controlled to enter the switching element through the matching network, and then an electrical state is changed, thereby controlling the transmission and disconnection of the signals. The switching element typically uses a diode to control the transmission and disconnection.

In some embodiments, the RF switch 131 includes a diode.

In the embodiment of the present disclosure, the RF switch 131 is selected as the switching circuit, which may transmit signals in a high-frequency band without losing almost any energy. For example, the RF switch has a very low insertion loss, which does not cause a degradation in the quality of the MRI signal and may improve the signal-to-noise ratio of the RF coil.

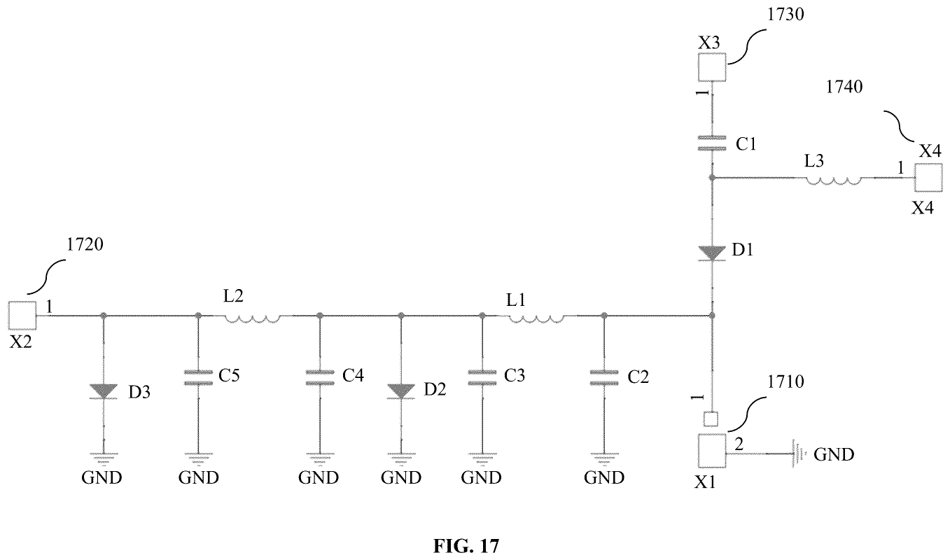

Related descriptions regarding the switching circuit may be found in FIG. 17 and related descriptions hereinafter.

FIG. 7 is a schematic diagram illustrating an exemplary first printed circuit board according to some embodiments of the present disclosure.

In some embodiments, the coil interface device 10 further includes a first printed circuit board 16, as shown in FIG. 7. The quick disconnect connector 11, the preamplifier 12, the switching circuit 13, the transmitter channel interface 31, and the receiver channel interface 41 are all integrated on the first printed circuit board 16.

The coil interface device includes a quick disconnect connector, a preamplifier, a switching circuit, a transmitter channel interface, and a receiver channel interface, and each component needs to be connected by a circuit. In order to enhance the stability and performance of the circuit, the quick disconnect connector 11, the preamplifier 12, the switching circuit 13, the transmitter channel interface 31, and the receiver channel interface 41 are all integrated in the first printed circuit board 16, which may realize the circuit connection between each component. Compared to the traditional way of connecting with wires, the integration on the first printed circuit board 16 makes the circuit connection between the quick disconnect connector 11, the preamplifier 12, the switching circuit 13, the transmitter channel interface 31, and the receiver channel interface 41 fast, precise, and reliable.

The printed circuit board refers to an integrated circuit used in one of the core technologies of electronic manufacturing. The printed circuit board is a support body of electronic components and a carrier of electrical connections of electronic components. This technology allows electrically conductive circuits and electronic components to be bonded to the same piece of non-conductive material to form a stationary electronic assembly, with the connections between these circuits and components consisting of a layer of conductors such as copper foil.

The printed circuit board may accommodate a plurality of electrical components in a relatively small space and may be produced automatically. Relative to traditional circuit boards that connect electronic components with wires, the printed circuit board uses printing to complete the conductive channel topography on the board to make circuit connections of electronic components fast, precise, and reliable. The main function is to make a variety of electronic components through the circuit connection, play the role of conduction and transmission.

In some embodiments, the first printed circuit board 16 may include lines with a graphic surface, a dielectric layer, a conductive hole, a solder resist ink, a silkscreen, etc. The first printed circuit board 16 takes an insulating plate as a substrate, and attach the insulating plate (cut into a certain size) with at least one conductive pattern, and provided with holes (such as component holes, fastening holes, metallization holes, etc.). The first printed circuit board 16 is used for placing electronic components to achieve interconnection of electronic components. Depending on a count of layers of the printed circuit board circuit, the first printed circuit board 16 may include a single board, a double board, a multilayer board, or the like.

In some embodiments, the RF coil 20 is an RF receiver coil.

The RF receiver coil refer to a receiver coil designed based on information about the shape and size of different objects. The RF receiver coil may be a surface coil (e.g., a coil that may be placed on a surface of the object to be imaged). The RF receiver coil is a coil that receives the MRI signals with high signal strength due to its close proximity to the imaging region, which improves the signal-to-noise ratio of an image. In some embodiments, the RF signals may be the MRI signals.

As shown in FIG. 8, FIG. 8 is a schematic diagram illustrating another exemplary receiver channel interface according to some embodiments of the present disclosure.

In some embodiments, the RF receiver coil is connected to one end of the coil interface device 10 and the other end of the coil interface device 10 includes a receiver channel interface 41. The receiver channel interface 41 is configured to be connected to the receiver channel of the MRI system. In some embodiments, the receiver channel interface may be configured to be detachably connected with the receiver channel of the MRI system.

The receiver channel interface 41 refers to an interface matching a system interface of the MRI system for connecting to the system interface in the MRI system to access the RF receiver coil into the MRI system.

In some embodiments, the RF receiver coil is connected to one end of the coil interface device 10. The connection includes a soldering connection, a threaded connection, a plug-in connection, a snap connection, or the like. In some embodiments, the welding connection may be detachable welding, such as a tin soldering connection. Utilizing the characteristics of the tin soldering connection, the RF receiver coil may also be removed from one end of the coil interface device after being soldered and connected to the coil interface device.

In some embodiments, one end of the coil interface device may also be detachably connected to the RF coil. For example, the one end of the coil interface device may be connected to the RF receiver coil via a quick disconnect connector.

In this embodiment, realizing the fast detachable connection between the RF receiver coil and the coil interface device through the quick plug interface may enhance the convenience and stability of the connection of the RF coil.

FIG. 9A is a schematic diagram illustrating an exemplary coil interface device according to some embodiments of the present disclosure.

In some embodiments, as shown in FIG. 9A, the coil interface device 10 includes a coil tuning device 14, a preamplifier 12, a channel interface (e.g., a receiver channel interface 41, a transmitter channer interface). The coil tuning device 14 is connected between the RF coil 20 and the preamplifier 12.

The coil tuning device 14 is configured to perform a tuning process for an RF coil, and the coil tuning device 14 may include a variable capacitor and an adjusting unit, or the like. A capacitance value of the variable capacitor may be adjusted by the adjusting unit to realize the tuning process of the RF coil.

In this embodiment, the coil tuning device 14 is provided between the RF coil 20 (e.g., the RF receiver coil and the integrated transceiver coil) and the preamplifier 12, and the preamplifier 12 may be connected to the receiver channel interface 41 so that the RF coil 20 may be tuned to adjust an oscillation frequency of the RF coil to a nuclear magnetic resonance frequency. Thus, the RF coil 20 may receive a maximum MRI signal and improve a signal-to-noise ratio of an image and an image quality. Additionally, the preamplifier 12 is provided between the coil tuning device 14 and the receiver channel interface 41, which may amplify the received MRI signals, reduce the relative influence of external interference, and further increase the signal-to-noise ratio of the image.

FIG. 9B is a schematic diagram illustrating an exemplary coil tuning device according to some embodiments of the present disclosure. In some embodiments, the coil interface device 10 does not include a coil tuning device 14 within, and the RF coil 20 includes or is connected to the coil tuning device 14. The coil tuning device 14 is configured to be detachably connected to the RF coil 20 via a soldering connection. The detachable soldering connection may include a tin soldering connection. As shown in FIG. 9B, the coil tuning device 14 is detachably connected to the RF coil 20 via two soldered joints. The coil tuning device 14 is connected to the quick disconnect connector of the coil interface device 10 via a cable.

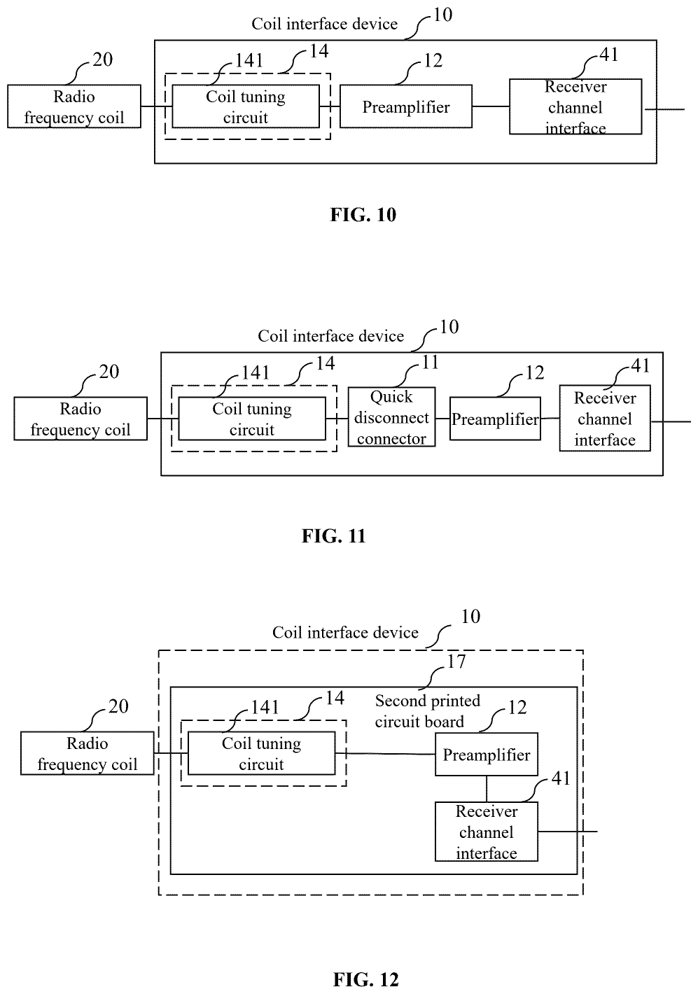

FIG. 10 is a schematic diagram illustrating an exemplary coil tuning circuit according to some embodiments of the present disclosure.

As shown in FIG. 10, in some embodiments, the coil tuning device 14 may include a coil tuning circuit 141. The coil tuning circuit 141 is connected between the RF receiver coil and the preamplifier 12.

The coil tuning circuit may realize a signal filtering and selection, which mainly utilizes a principle that inductors and capacitors have different impedance characteristics for signals of different frequencies. The coil tuning circuit may be composed in different ways depending on a specific application requirement and a specific frequency range.

Optionally, the coil tuning circuit 141 may be a series inductor-capacitor tuning circuit and a parallel inductor-capacitor tuning circuit, etc. The series inductor-capacitor tuning circuit includes an inductor and a capacitor connected in series. When a frequency and a resonance frequency of an input signal are the same, an impedances of the inductor and the capacitor cancel out respectively, forming a low impedance path and the signal passes through. Whereas, when the frequency of the input signal is different from the resonance frequency, the impedances of the inductor and the capacitor do not cancel out, forming a high impedance path and the signal is filtered out. The parallel inductor-capacitor tuning circuit consists of an inductor and capacitor connected in parallel. When the frequency of the input signal is the same as the resonance frequency, the inductor and the capacitor are in a high impedance state and the signal is filtered out. Whereas, when the frequency of the input signal is different from the resonance frequency, the inductor and capacitor are not in the high impedance and the signal passes through.

Optionally, the coil tuning circuit 141 may also employ a transformer tuning circuit and a resistor-capacitor tuning circuit, etc. Certainly, the transformer tuning circuit realize the tuning of the signal by changing a ratio of windings of the transformer. By adjusting the ratio of windings of the transformer, an effective value and the resonance frequency of the inductor may be changed. And the resistor-capacitor tuning circuit realizes the signal tuning through the combination of resistor and capacitor.

In the embodiment of the present disclosure, the coil tuning circuit 141 is provided in the coil tuning device 14, and one end of the coil tuning circuit 141 is be configured to be connected to the RF receiver coil, so that the RF coil may be tuned and processed by the coil tuning circuit 141. Different inductor-capacitor compositions may be used according to specific application requirements and different frequency ranges. The other end of the coil tuning circuit 141 is connected to the preamplifier to amplify the MRI signals received by the RF receiver coil and improve the signal-to-noise ratio of the RF coil.

FIG. 11 is a schematic diagram illustrating an exemplary coil interface device according to other embodiments of the present disclosure.

In some embodiments, one end of the coil tuning device 14 is be configured to be connected to the RF receiver coil, the other end of the coil tuning device 14 is connected to one end of the quick disconnect connector 11, and the other end of the quick disconnect connector 11 is connected to the preamplifier 12.

Further, as shown in FIG. 11, the coil tuning device 14 includes the coil tuning circuit 141 connected to one end of the RF receiver coil, one end of the coil tuning circuit 141 is be configured to be connected to the RF receiver coil, the other end of the coil tuning circuit 141 is connected to one end of the quick disconnect connector 11, and the other end of the quick disconnect connector 11 is connected to the preamplifier 12.

In the embodiment of the present disclosure, one end of the coil tuning device 14 is be configured to be connected to the RF receiver coil, and the other end of the coil tuning device 14 is connected to one end of the quick disconnect connector 11, which allows for the coil tuning device to be simply and conveniently connected to the preamplifier through the quick disconnect connector. When the other end of the coil tuning device 14 is connected to the RF receiver coil, the RF receiver coil may be accessed to the MRI system through the connection between the receiver channel interface and the system interface of the MRI system in the case that the coil tuning device 14 is connected to the preamplifier 12 through the quick disconnect connector 11.

In this coil interface device, the coil tuning device may be simply and conveniently connected to the preamplifier by connecting the coil tuning device to the quick disconnect connector. The quick disconnect connector may be connected and disassembled quickly, which may effectively reduce the equipment failures caused by caused by poor connection or poor contact, thereby improving the reliability of the device. In addition, the quick disconnect connector is very convenient to use, and may quickly connect and disassemble electrical devices, which also improves the efficiency of the maintenance of the MRI system.

FIG. 12 is a schematic diagram illustrating an exemplary printed circuit board according to some embodiments of the present disclosure.

In some embodiments, as shown in FIG. 12, the coil interface device 10 further includes a second printed circuit board 17. The coil tuning device 14, the preamplifier 12, and the Channel interface are provided on the second printed circuit board 17. The RF receiver coil may be fixed to the second printed circuit board 17 by a soldering connection.

The coil interface device includes a coil tuning device, a preamplifier, and a receiver channel interface. The coil tuning device, the preamplifier, and the receiver channel interface need to be connected to each other by a circuit. In order to enhance the stability and the performance of the circuit, the coil tuning device, the preamplifier, and the receiver channel interface may be integrated on the printed circuit board.

The second printed circuit board 17 may have a same or similar structure with the first printed circuit board 16, which is not described herein.

In the embodiment of the present disclosure, by providing the coil tuning device 14, the preamplifier 12, and the receiver channel interface 41 on the second printed circuit board 17, the circuit connection between the coil tuning device 14, the preamplifier 12, and the receiver channel interface 41 is realized. The circuit connection between the coil tuning device 14, the preamplifier 12, and the receiver channel interface 41 may be realized rapidly, precisely, and reliably. Alternatively, the RF receiver coil may be soldered to the second printed circuit board 17 and close to a side of the coil tuning device 14, the RF receiver coil may be connected to a system interface of the MRI system through the receiver channel interface provided on the second printed circuit board 17, to realize accessing the RF receiver coil into the MRI system.

When the coil tuning device and the preamplifier are integrated on a printed circuit board, the coil tuning device and the preamplifier may be directly connected by a circuit, and there is no need to use other connecting devices to realize the circuit connection between the coil tuning device and the preamplifier. When the coil tunning device and the preamplifier are not provided on the same printed circuit board, the coil tunning device and the preamplifier need to be connected by certain connecting devices.

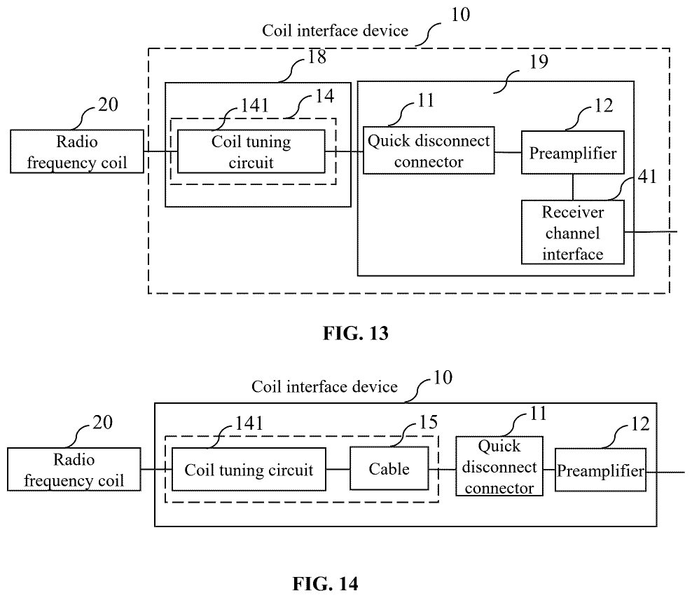

FIG. 13 is a schematic diagram illustrating an exemplary third printed circuit board according to some embodiments of the present disclosure.

In some embodiments, the coil tuning device includes a third printed circuit board 18, with a coil tuning circuit provided on the third printed circuit board 18. The coil interface device 10 further includes a fourth printed circuit board 19. The quick disconnect connector 11, the preamplifier 12, and the receiver channel interface 41 are provided on the fourth printed circuit board 19. The circuit connections between the quick disconnect connector 11, the preamplifier 12, and the receiver channel interface 41 may be realized. When the RF receiver coil is soldered to the third printed circuit board 18, the RF receiver coil may be easily accessed to the MRI system by the connection with the quick disconnect connector.

When the coil tuning device is connected to the preamplifier via the quick disconnect connector, the coil tuning device and the preamplifier are not integrated on a printed circuit board.

The structure of the third printed circuit board 18 may be the same structure as that of the second printed circuit board 17, including the lines with graphic surfaces, a dielectric layer, a conductive hole, a solder resist ink, a silk screen, or the like. According to the actual application requirements, the third printed circuit board 18 may also be selected from printed circuit boards with different layers of circuit, which may include a single board, a double board, a multilayer board, or the like.

In the embodiment of the present disclosure, the coil tuning device 14 is provided on the third printed circuit board 18, and the coil tuning device 14 may be connected to the preamplifier 12 through the quick disconnect connector 11. Furthermore, the RF receiver coil may be soldered on the third printed circuit board 18. For example, the RF receiver coil may be connected to the MRI system through the connection between the receiver channel interface 41 and the system interface of the MRI system in the case where the coil tuning device 14 is connected to the preamplifier 12 through the quick disconnect connector 11.

In the MRI system provided by embodiments of the present disclosure, the coil tuning device further includes a third printed circuit board. The coil tuning device is provided on the third printed circuit board. In the coil interface device, the coil tuning device may be provided on the third printed circuit board by providing the third printed circuit board in the coil tuning device, which provides an alternative way of providing the coil tuning device, realizing the circuit connection between the coil tuning device and the preamplifier through the quick disconnect connector.

Because the coil tuning device and the preamplifier of the above embodiment are not on the same printed circuit board, and the coil tuning circuit board is provided on the third printed circuit board, it is necessary to provide another printed circuit board for the preamplifier to enable the circuit connection between the quick disconnect connector, the preamplifier, and the receiver channel interface.

The fourth printed circuit board 19 may be the same as the second printed circuit board 17 or the third printed circuit board 18, including lines with graphic surfaces, a dielectric layer, a conductive hole, a solder resist ink, and a silkscreen, or the like. According to the actual application requirements, the fourth printed circuit board 19 may also be selected from printed circuit boards with different layers of circuit, which may include a single board, a double board, a multilayer board, or the like.

In some embodiments, the present disclosure also provides a coil interface device of an MRI system. One end of the coil interface device is soldered to an RF coil, and the other end of the coil interface device includes a receiver channel interface. The receiver channel interface matches a system interface in the MRI system. The coil interface device further includes a coil tuning device and a preamplifier. The coil tuning device is connected between the RF coil and the preamplifier, and the preamplifier is connected to the receiver channel interface.

FIG. 14 is a schematic diagram illustrating an exemplary cable according to some embodiments of the present disclosure.

As shown in FIG. 14, in some embodiments, the coil interface device further includes a cable 15, and a circuit connection between the coil tuning device 14 and the quick disconnect connector 11 may be realized by connecting the cable 15.

The cable 15 may be an RF cable, including a conductor, an insulation layer, a shield, or the like. The conductor is usually made of materials such as copper wire or copper tape. The insulating layer is made of materials with good high-frequency performance such as foam polyethylene, solid polyethylene, etc. The shielding layer is made of materials such as copper mesh, aluminum foil, etc., which may shield interference from external electromagnetic wave. A type of RF cable may also be determined according to the actual application requirements. For example, the type of RF cable may include a coaxial cable, a balanced cable, and tube cable, etc.

In the embodiment of the present disclosure, connecting the coil tuning device 14 to the quick disconnect connector 11 via the cable 15 reduces a certain amount of signal loss during the transmission of the MRI signals.

In some embodiments, the coil interface device further includes a coil type determination module configured to determine a type of the RF coil. The coil type determination module causes the RF coil to be connected to a circuit corresponding to the type of the RF coil. Types of the RF coil includes an integrated transceiver coil, a receiver coil, and a transmitter coil. Each type corresponds to a different circuit. For example, the interface device of the integrated transceiver coil includes a switching circuit.

The coil type determination module is a functional module configured to identify or determine a type of a RF coil that is connected with the coil type determination module. In some embodiments, the coil type determination module may be a separately provided functional module or may be implemented by a processor.

In some embodiments, the coil type determination module may obtain information related to the coil type from the RF coil after the RF coil is accessed (or connected with the MRI system) and determine the type of the RF coil based on the obtained information.

In some embodiments, the coil type determination module may also invoke an image sensor (e.g., an image sensor provided in the MRI system) to obtain an image of the RF coil and determine the type of the RF coil according to an image recognition algorithm. In some embodiments, the coil type determination module may determine the type of the RF coil based on a circuit detection. In some embodiments, the coil type determination module may be a module that determines the type of the RF coil based on a physical detection on the interface (e.g., the plugging shape is the same, but touch spots within the interface are different).

When the coil type determination module determines the type of the RF coil, the coil type determination module enables the RF coil to be connected to a circuit that corresponds to the type of the RF coil.

In embodiments of the present disclosure, the coil type determination module allows automatic determination of the RF coil, thereby eliminating the need for manual confirmation of access of the RF coil, achieving the purpose of plug-and-play use of the RF coil, and enhancing the convenience of accessing the RF coil. The coil type determination module avoids plugging in wrong coils and improves compatibility.

One end of the coil interface device is soldered to an RF coil, and the other end of the coil interface device includes a receiver channel interface. The receiver channel interface matches a system interface of the MRI system. The RF coil is accessed in the MRI system through the connection between the receiver channel interface and the system interface. When performing an MRI process, the scanning bed and the coil interface device are accessed into the scanning cavity. In the MRI system, the receiver channel interface may be simply and conveniently connected to the system interface by providing the receiver channel interface in the coil interface device that matches the system interface of the MRI system. In this way, when the RF coil is soldered to the coil interface device, the receiver channel interface of the coil interface device may be connected to the system interface of the MRI system to cause the RF coil to be connected to the MRI system, thereby realizing the compatibility of the RF coil with the MRI system.

In the MRI system, not only an impedance of an RF transmitter coil is required to match an impedance of an RF transmission line that connects the RF transmitter coil with a preamplifier, but also an intrinsic frequency of the RF coil (e.g., the RF transmitter coil) is required to correspond to a magnetic field strength of the MRI system. Thus, the RF coil of the MRI device is designed to resonate at a resonance frequency of hydrogen protons to realize an excitation of MRI signals and a reception of maximum MRI signals. If the intrinsic frequency of the RF coil is not corresponding to the magnetic field strength of the MRI system, a signal-to-noise ratio of an image of the MRI system may be reduced. In order to ensure the signal-to-noise ratio of the image and the image quality as much as possible, the RF coil needs to be tuned to adjust an oscillation frequency of the RF coil to a nuclear magnetic resonance frequency so that the RF coil may receive the maximum MRI signal.

FIG. 15 is a schematic diagram illustrating an exemplary magnetic resonance imaging (MRI) system according to some embodiments of the present disclosure. As shown in FIG. 15, the MRI system may include a scanning bed 1510, a scanning cavity 1520, and a coil interface device 1530.

The coil interface device 1530 is configured to connect the MRI system and a radio frequency (RF) coil. The coil interface device 1530 includes a preamplifier 1531 and a quick disconnect connector 1532. One end of the quick disconnect connector 1532 is connected to the preamplifier 1531, and another end is connected to the RF coil. The quick disconnect connector 1532 is configured to be detachably connected to the RF coil.

More descriptions regarding each module in the MRI system may be found in related descriptions in FIGS. 2-14.

FIG. 16 is a schematic diagram illustrating an exemplary structure of a quick disconnect connector according to some embodiments of the present disclosure.

As shown in FIG. 16, the quick disconnect connector includes a socket port 1610 and a plug interface 1620. The socket port 1610 is connected to the preamplifier, and plug interface 1620 is configured to be connected to the RF coil.

FIG. 17 is a schematic diagram illustrating an exemplary circuit structure of a switching circuit according to some embodiments of the present disclosure.

As shown in FIG. 17, the switching circuit includes a first interface 1710, a second interface 1720, a third interface 1730, and a fourth interface 1740. The first interface 1710 is connected to the quick disconnect connector. The second interface 1720 is a receiver link and is connected to the preamplifier. The third interface 1730 is a transmitter link and is configured to be connected to the transmitter channel of the MRI system. The fourth interface 1740 is configured to be connected to the MRI system for controlling the switches in the MRI system. As shown in FIG. 17, the switching circuit further includes a plurality of capacitors (e.g., C1, C2, C3, C4), a plurality of inductors (e.g., L1, L2, L3), and a plurality of diodes (e.g., D1, D2, D3).

The functions of the relevant connecting components for each interface have been described previously and may not be repeated here.

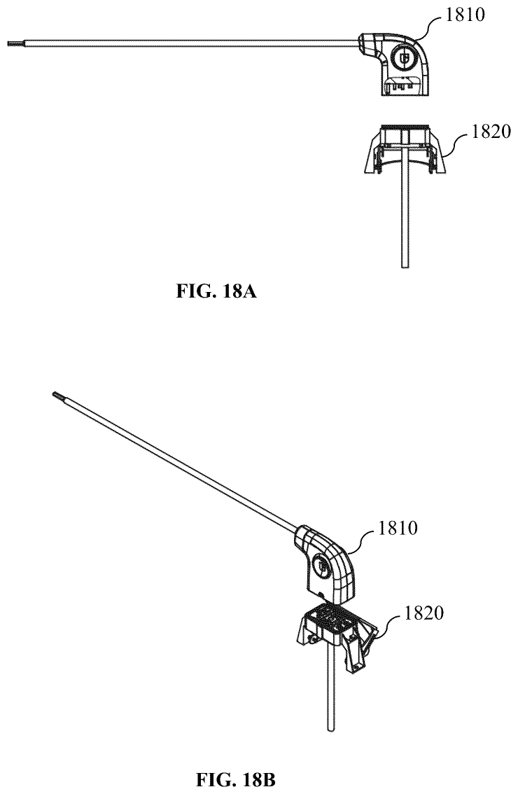

FIG. 18A and FIG. 18B are schematic diagrams illustrating an exemplary structure of a system interface according to some embodiments of the present disclosure.

As shown in FIG. 18A and FIG. 18B, the system interface includes a plug interface 1810 and a socket interface 1820. The plug interface 1810 is connected to the coil interface device and the socket interface 1820 is configured to be connected to the MRI system.

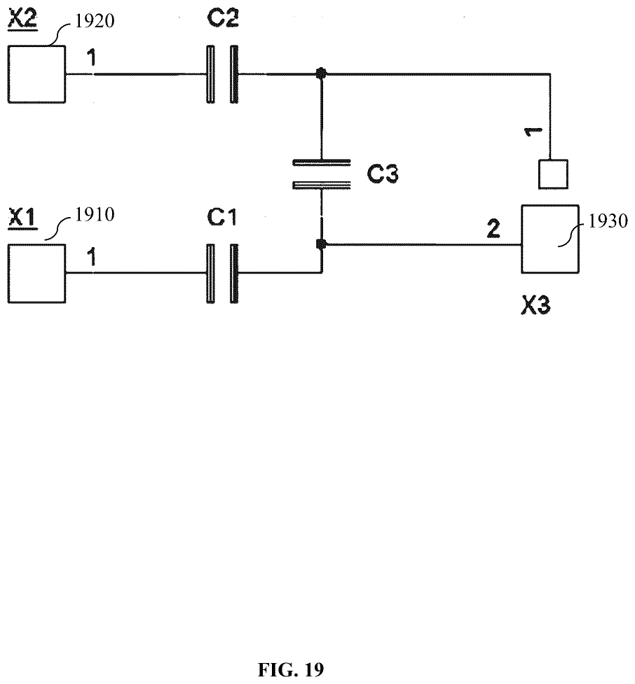

FIG. 19 is a schematic diagram illustrating an exemplary coil tuning circuit according to some embodiments of the present disclosure.

As shown in FIG. 19, the coil tuning circuit includes a first connection point 1910, a second connection point 1920, and a third connection point 1930. As shown in FIG. 19, the coil tuning circuit further includes a plurality of capacitors (e.g., C1, C2, C3).

One of C1 and C2 in FIG. 19 is an adjustable capacitor, which may be used for frequency adjustment. C3 is also an adjustable capacitor, which is used for frequency adjustment in conjunction with C1 and C2.

The first connection point 1910 and the second connection point 1920 may be configured to be connected to the RF coil. In some embodiments, the first connection point 1910 and the second connection point 1920 may be soldered points to be fixedly connected to the RF coil by soldering. In some embodiments, the first connection point 1910 and the second connection point 1920 may be detachable connection points, e.g., a carabiner, a socket, etc., to be detachably connected to the RF coil.

The third connection point 1930 is configured to be connected to a cable. The coil tuning circuit is connected to the quick disconnect connector via the cable. Similarly, the third connection point 1930 may be directly connected to the quick disconnect connector.

In some embodiments, the third connection point 1930 is a solder point.

Based on the same inventive concept, some embodiments of the present disclosure also provide an MRI system. The MRI system includes a transmitter channel, a receiver channel, a coil interface device, a scanning bed, and a scanning cavity. The transmitter channel is configured to transmit RF signals, and the receiver channel is configured to receive RF signals. The scanning bed is configured to place an object thereon. The scanning cavity may be configured to accommodate at least a portion of imaging devices of the MRI system. The coil interface device includes a preamplifier and a quick disconnect connector. One end of the quick disconnect connector is connected to the preamplifier, and the other end of the quick disconnect connector is connected to an RF coil. The quick disconnect connector is be configured to be detachably connected to the RF coil.

More description regarding the coil interface device of the MRI system may be found in the description above in the present disclosure.

Having thus described the basic concepts, it may be rather apparent to those skilled in the art after reading this detailed disclosure that the foregoing detailed disclosure is intended to be presented by way of example only and is not limiting. Although not explicitly stated here, those skilled in the art may make various modifications, improvements, and amendments to the present disclosure. These alterations, improvements, and amendments are intended to be suggested by this disclosure and are within the spirit and scope of the exemplary embodiments of the present disclosure.

Moreover, certain terminology has been used to describe embodiments of the present disclosure. For example, the terms “one embodiment,” “an embodiment,” and/or “some embodiments” mean that a particular feature, structure, or feature described in connection with the embodiment is included in at least one embodiment of the present disclosure. Therefore, it is emphasized and should be appreciated that two or more references to “an embodiment”, “one embodiment”, or “an alternative embodiment” in various portions of the present disclosure are not necessarily all referring to the same embodiment. In addition, some features, structures, or characteristics of one or more embodiments in the present disclosure may be properly combined.

Furthermore, the recited order of processing elements or sequences, or the use of numbers, letters, or other designations, therefore, is not intended to limit the claimed processes and methods to any order except as may be specified in the claims. Although the above disclosure discusses some embodiments of the invention currently considered useful by various examples, it should be understood that such details are for illustrative purposes only, and the additional claims are not limited to the disclosed embodiments. Instead, the claims are intended to cover all combinations of corrections and equivalents consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be appreciated that in the foregoing description of embodiments of the present disclosure, various features are sometimes grouped together in a single embodiment, figure, or description thereof for the purpose of streamlining the disclosure aiding in the understanding of one or more of the various embodiments. However, this disclosure does not mean that object of the present disclosure requires more features than the features mentioned in the claims. Rather, claimed subject matter may lie in less than all features of a single foregoing disclosed embodiment.

In some embodiments, the numbers expressing quantities or properties used to describe and claim certain embodiments of the present disclosure are to be understood as being modified in some instances by the term “about”, “approximate”, or “substantially”. For example, “about”, “approximate”, or “substantially” may indicate ±20% variation of the value it describes, unless otherwise stated. Accordingly, in some embodiments, the numerical parameters set forth in the written description and attached claims are approximations that may vary depending upon the desired properties sought to be obtained by a particular embodiment. In some embodiments, the numerical parameters should be construed in light of the number of reported significant digits and by applying ordinary rounding techniques. Notwithstanding that the numerical ranges and parameters setting forth the broad scope of some embodiments of the present disclosure are approximations, the numerical values set forth in the specific examples are reported as precisely as practicable.

Each of the patents, patent applications, publications of patent applications, and other material, such as articles, books, specifications, publications, documents, things, and/or the like, referenced herein is hereby incorporated herein by this reference in its entirety for all purposes. History application documents that are inconsistent or conflictive with the contents of the present disclosure are excluded, as well as documents (currently or subsequently appended to the present specification) limiting the broadest scope of the claims of the present disclosure. By way of example, should there be any inconsistency or conflict between the description, definition, and/or the use of a term associated with any of the incorporated material and that associated with the present document, the description, definition, and/or the use of the term in the present document shall prevail.

In closing, it is to be understood that the embodiments of the present disclosure disclosed herein are illustrative of the principles of the embodiments of the present disclosure. Other modifications that may be employed may be within the scope of the present disclosure. Thus, by way of example, but not of limitation, alternative configurations of the embodiments of the present disclosure may be utilized in accordance with the teachings herein. Accordingly, embodiments of the present disclosure are not limited to that precisely as shown and described.

What is claimed is:

1. A magnetic resonance imaging (MRI) system, comprising a receiver channel configured to receive radio frequency signals, and a coil interface device configured to connect the MRI system with a radio frequency (RF) coil, wherein the coil interface device comprises:
a preamplifier;
a quick disconnect connector, wherein one end of the quick disconnect connector is connected to the preamplifier and another end is configured to be connected to the RF coil, and the quick disconnect connector is configured to be detachably connected to the RF coil; and
a receiver channel interface, wherein the receiver channel interface is configured to be connected to the receiver channel.

2. The MRI system of claim 1, further comprising a transmitter channel configured to transmit radio frequency signals, and the coil interface device further comprising a switching circuit, wherein a first end of the switching circuit is connected to the quick disconnect connector, a second end of the switching circuit is configured to be connected to the transmitter channel, and a third end of the switching circuit is configured to be connected to the receiver channel via the preamplifier.

3. The MRI system of claim 2, the coil interface device further comprising a transmitter channel interface, wherein the transmitter channel interface is configured to be connected between the switching circuit and the transmitter channel.

4. The MRI system of claim 3, wherein the transmitter channel interface is configured to be detachably connected to the transmitter channel; and the receiver channel interface is configured to be detachably connected to the receiver channel.

5. The MRI system of claim 4, wherein the transmitter channel interface is detachably connected to the transmitter channel through an RF pin and an RF socket; or the receiver channel interface is detachably connected to the receiver channel through an RF pin and an RF socket.

6. The MRI system of claim 3, the coil interface device further comprising a printed circuit board, wherein the quick disconnect connector, the preamplifier, the switching circuit, the transmitter channel interface, and the receiver channel interface are integrated on the printed circuit board.

7. The MRI system of claim 1, the coil interface device further comprising a coil tuning device, wherein the coil tuning device is configured to be connected between the RF coil and the preamplifier.

8. The MRI system of claim 1, wherein the coil interface device is configured to be connected to a coil tuning device via the quick disconnect connector and a cable, wherein the cable is connected to the coil tuning device and the quick disconnect connector, respectively.

9. The MRI system of claim 8, wherein the coil tuning device is configured to be detachably connected to the RF coil via a tin soldering connection.

10. The MRI system of claim 7, the coil interface device further comprising a second printed circuit board, wherein the coil tuning device, the preamplifier, and the receiver channel interface are integrated on the second printed circuit board.

11. The MRI system of claim 7, wherein
the coil tuning device includes a third printed circuit board, and the coil tuning circuit is provided on the third printed circuit board; and
the coil interface device further comprises a fourth printed circuit board, wherein the preamplifier, the quick disconnect connector, and the receiver channel interface are integrated on the fourth printed circuit board.

12. The MRI system of claim 1, wherein the quick disconnect connector is detachably connected to the RF coil via a separation quick locking assembly (SQLA) quick plug and socket.

13. The MRI system of claim 1, the coil interface device further comprising a plurality of quick disconnect connectors, wherein the plurality of quick disconnect connectors are configured to be detachably connected to a plurality of channels of the RF coil.

14. The MRI system of claim 1, wherein the quick disconnect connector includes a first quick disconnect connector and a second quick disconnect connector, the first quick disconnect connector is configured to be detachably connected to a channel of a first RF coil, and the second quick disconnect connector is configured to be detachably connected to a channel of a second RF coil, wherein
a first spatial range of the first RF coil is different from a second spatial range of the second RF coil, or a first polarized direction of the first RF coil is different from a second polarized direction of the second RF coil; and
the first quick disconnect connector is the same as the second quick disconnect connector.

15. The MRI system of claim 14, the coil interface device further comprising a first switch and a second switch, wherein the first switch is configured to control connection and disconnection of the first RF coil, and the second switch is configured to control connection and disconnection of the second RF coil.

16. The MRI system of claim 1, the coil interface device further comprising a coil type determination module configured to determine a type of the RF coil, and the coil type determination module causes the RF coil to be connected to a circuit corresponding to the type of the RF coil.

17. The MRI system of claim 1, wherein the RF coil is an RF receiver coil or an integrated RF transceiver coil.

18. A coil interface device, comprising:
a preamplifier; and
a quick disconnect connector, wherein one end of the quick disconnect connector is connected to the preamplifier and another end of the quick disconnect connector is configured to be connected to an RF coil, and the quick disconnect connector is configured to be detachably connected to the RF coil.

19. The coil interface device of claim 18, further comprising a coil tuning device, wherein the coil tuning device is configured to be connected between the quick disconnect connector RF coil and the preamplifier.

20. The coil interface device of claim 18, wherein the coil interface device is configured to be connected to the coil tuning device via the quick disconnect connector and a cable, wherein the cable is connected to the coil tuning device and the quick disconnect connector, respectively.
